(19) United States
(12) Patent Application Publication
(10) Pub. No.: US 2015/0282372 A1
(43) Pub. Date: Oct. 1, 2015

(54) CABLE CONNECTION METHOD FOR ELECTRONIC DEVICE AND JIG FOR CABLE CONNECTION

(71) Applicant: FUJITSU LIMITED, Kawasaki-shi (JP)

(72) Inventor: Yasutomo SAKURAI, Kawasaki (JP)

(73) Assignee: FUJITSU LIMITED, Kawasaki (JP)

(21) Appl. No.: 14/597,525

(22) Filed: Jan. 15, 2015

(30) Foreign Application Priority Data
Mar. 28, 2014 (JP) 2014-068609

(51) Int. Cl. H05K 7/14; H05K 7/18

(52) U.S. Cl. CPC H05K 7/1417; H05K 7/18; H05K 7/1487

(57) ABSTRACT

A cable connection method for an electronic device (such as a blade server), which includes: placing a jig in an arrangement location (such as a rack) in which the electronic device is to be arranged, and holding by a holder at least one of a cable and a connector member connected with the cable, the holder provided in a location in the jig corresponding to a connector attachment member in the electronic device; arranging the electronic device in the arrangement location; and connecting the connector member with the connector attachment member.

### CROSS-REFERENCE TO RELATED APPLICATION

This application is based upon and claims the benefit of priority of the prior Japanese Patent Application No. 2014-068609, filed on Mar. 28, 2014, the entire contents of which are incorporated herein by reference.

### FIELD

The embodiments discussed herein are related to a cable connection method for an electronic device, a jig, an electronic apparatus, and a rack device for cable connection.

### BACKGROUND

In general, a connector member connected with a cable is connected with a member which is provided in an electronic device and configured to be connected with the connector member (hereinafter such a member is also referred to as a connector attachment member) (see, for example, Japanese Laid-open Patent Publication No. 2011-222638). In such a cable connection work for an electronic device, there is a case where a work efficiency is desired to be improved.

Such technologies have been described, for example, in Japanese Laid-open Patent Publication No. 6-349354 and Japanese Laid-open Patent Publication No. 7-14445.

As an aspect of the embodiments discussed herein, an object is to improve a work efficiency at a time of a cable connection work.

### SUMMARY

According to an aspect of the invention, a cable connection method for an electronic device (such as a blade server) is disclosed, which includes: placing a jig in an arrangement location (such as a rack) in which the electronic device is to be arranged, and holding by a holder at least one of a cable and a connector member connected with the cable, the holder provided in a location in the jig corresponding to a connector attachment member in the electronic device; arranging the electronic device in the arrangement location; and connecting the connector member with the connector attachment member.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A is a perspective diagram of an electronic system including multiple electronic apparatuses according to a first embodiment;

FIG. 1B is a diagram illustrating a state where a cable routing work is completed before electronic devices are mounted on racks in the electronic system illustrated in FIG. 1A;

FIG. 2 is a perspective diagram of the electronic devices illustrated in FIG. 1A;

FIG. 3 is an exploded perspective diagram of the electronic device and a jig illustrated in FIG. 2;

FIG. 4 is a diagram illustrating a cable connection method for an electronic device according to the first embodiment;

FIG. 5A is a perspective diagram of an electronic system including multiple electronic apparatuses according to a second embodiment;

FIG. 5B is a diagram illustrating a state where a cable routing work is completed before racks on which electronic devices are mounted are installed in an arrangement space in the electronic system illustrated in FIG. 5A;

FIG. 6 is a perspective diagram of the electronic apparatus illustrated in FIG. 5A;

FIG. 7 is a diagram illustrating a cable connection method for an electronic device according to the second embodiment;

FIG. 8 is a diagram illustrating a cable connection method for an electronic device according to a third embodiment;

FIG. 9 is a diagram illustrating a state where a jig illustrated in FIG. 8 is removed from a cable;

FIG. 10 is a diagram illustrating a cable connection method for an electronic device according to a fourth embodiment;

FIG. 11 is a diagram illustrating a state where a jig illustrated in FIG. 10 is removed from a cable in a state of being divided into multiple divided members;

FIG. 12 is a diagram illustrating a cable connection method for an electronic device according to a fifth embodiment;

FIG. 13 is a diagram illustrating a modification of the cable connection method for an electronic device according to the fifth embodiment;

FIG. 14 is a diagram illustrating a cable connection method for an electronic device according to a sixth embodiment;

FIG. 15 is a diagram illustrating a cable connection method for an electronic device according to a seventh embodiment;

FIG. 16 is a diagram illustrating a first modification of the cable connection method for an electronic device according to the seventh embodiment; and

FIG. 17 is a diagram illustrating a second modification of the cable connection method for an electronic device according to the seventh embodiment.

### DESCRIPTION OF EMBODIMENTS

### First Embodiment

A first embodiment is described.

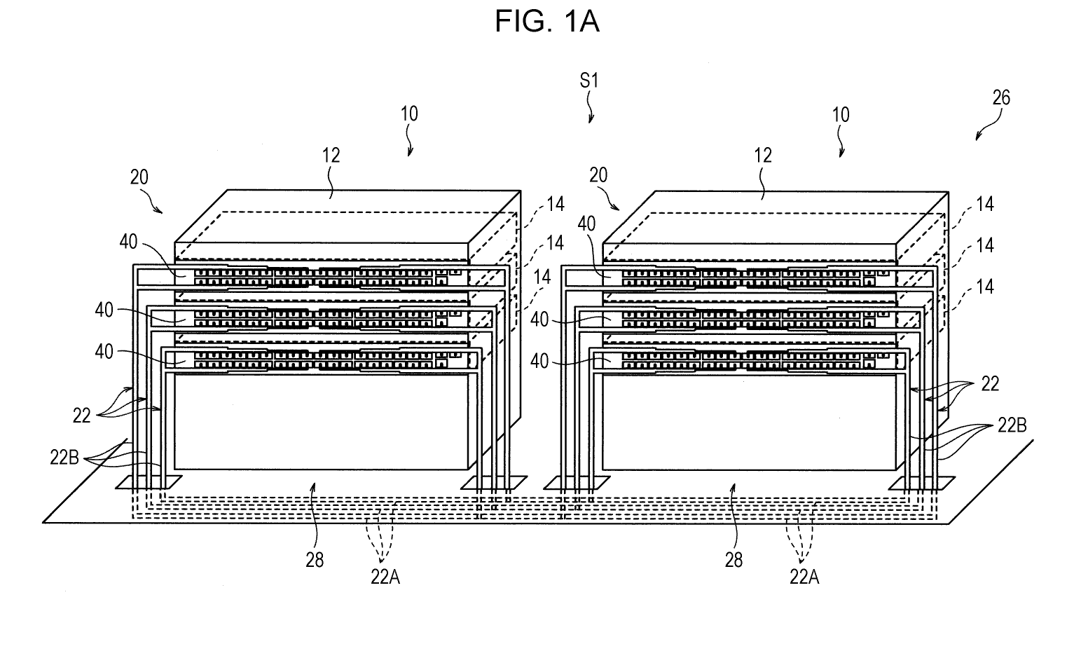

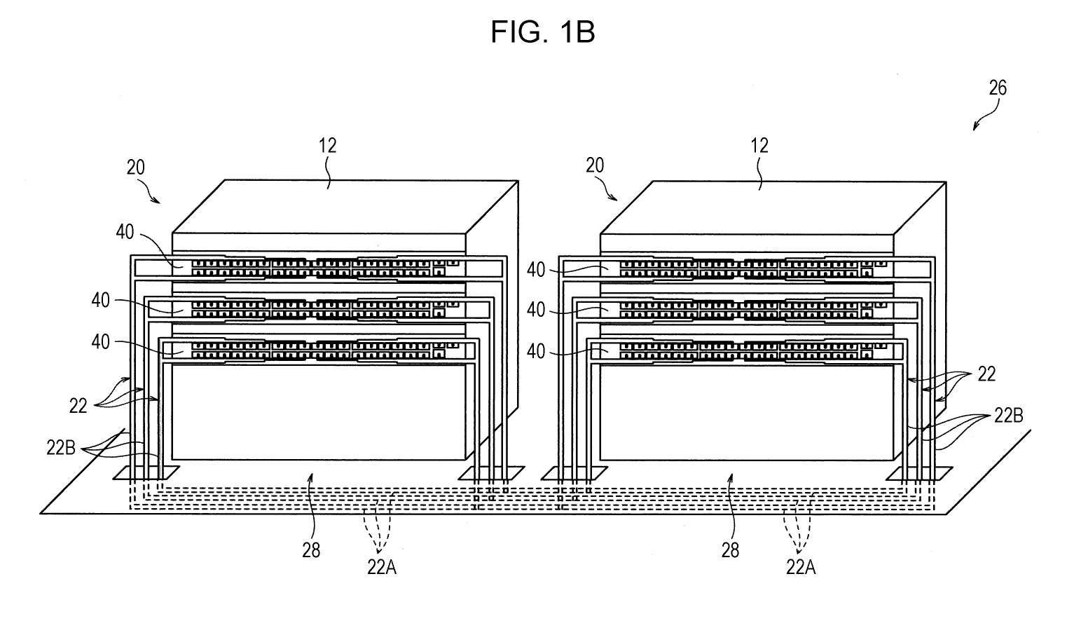

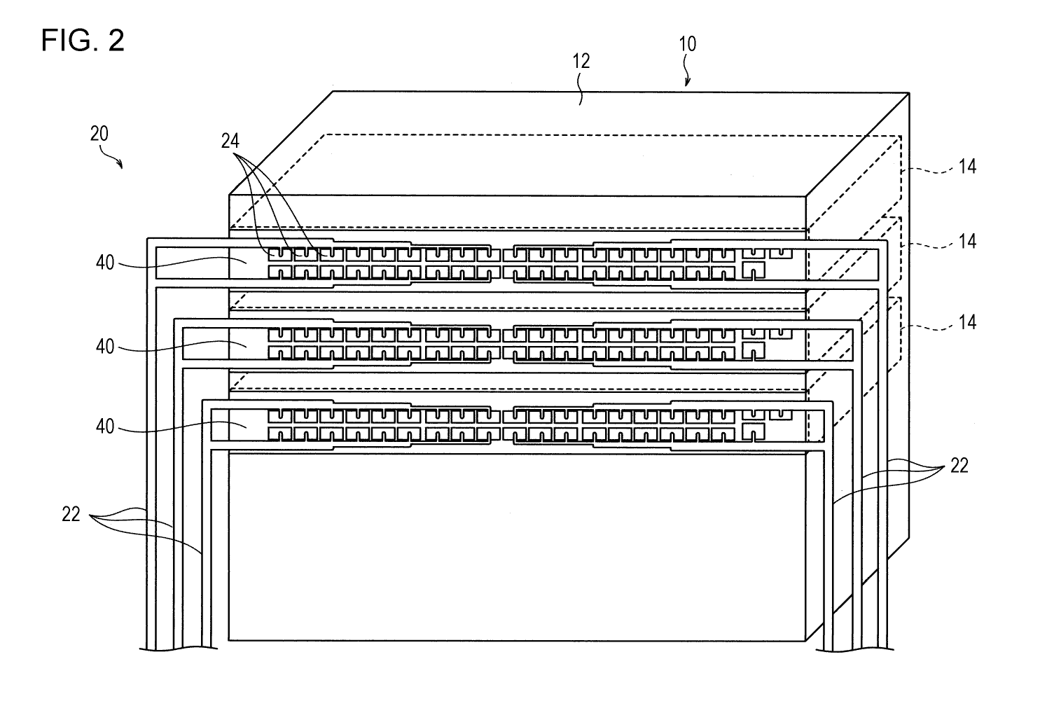

As illustrated in FIG. 1A, an electronic system 51 includes multiple electronic apparatuses 10. As illustrated in FIG. 2, each of the electronic apparatus 10 includes a rack 12 and multiple electronic devices 14. The rack 12 has a rectangular parallelepiped shape, for example. The electronic devices 14 are blade servers or routers, for example, and are mounted on respective levels of the rack 12.

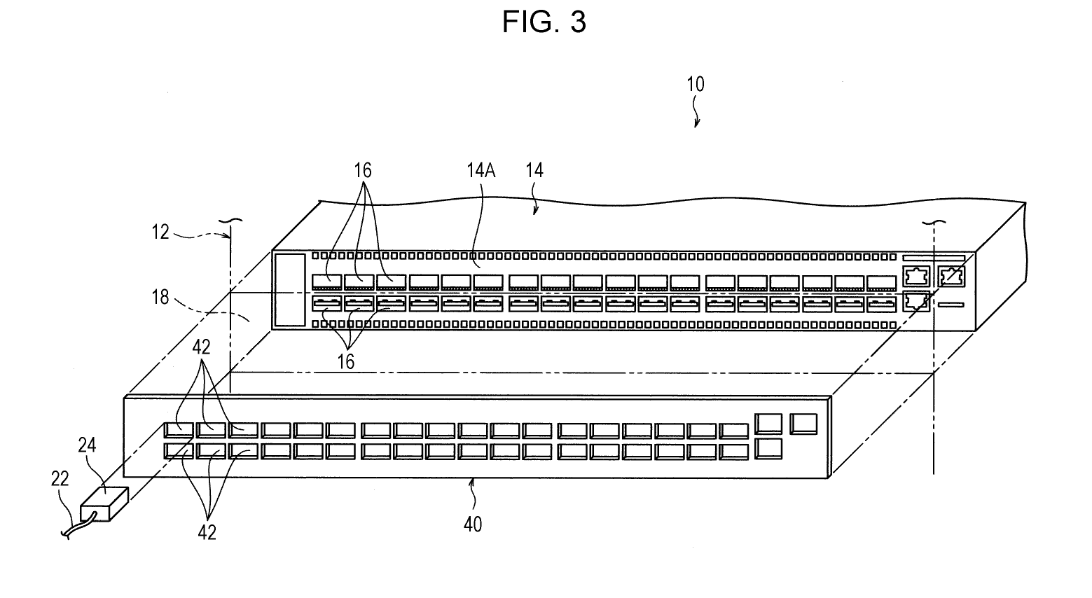

As illustrated in FIG. 3, each of the electronic devices 14 has multiple connector attachment members 16. Those connector attachment members 16 are provided and arranged on the back surface 14A of the electronic device 14 and are exposed in the back surface 14A of the electronic device 14. The back surface 14A of the electronic device 14 is an example of a cable connection surface.

In the state where the electronic device 14 is mounted in the rack 12, the entire back surface 14A including the multiple connector attachment members 16 is exposed to the back side from the rack 12 through a slit 18 opened in the back surface of the rack. The slit 18 has a rectangular shape with a substantially same shape and size as those of the back surface 14A of the electronic device 14. Incidentally, the entire back surface of the rack 12 may be opened without forming the slit 18.

A connector member 24 connected with an end of a cable 22 is connected with each of the multiple connector attachment members 16 which are exposed to the back side from the rack 12. The connector member 24 is connected with the connector attachment member 16 by using a jig 40 which is provided so as to face the back surface 14A of the electronic device 14.

The jig 40 is formed in a rectangular plate form and has almost the same shape and size as those of the back surface 14A of the electronic device 14 and the slit 18. As is described later, the jig 40 is provided in the rack 12 while being placed inside the slit 18. This jig 40 has multiple holes 42 passing through the jig 40 in the thickness direction.

The multiple holes 42 are formed corresponding to the multiple connector attachment members 16 so as to be aligned with respective arrangement locations of the multiple connector attachment members 16 in a state where the jig 40 is placed in the rack 12. Each of the multiple holes 42 is an example of an opening. As described later, a connector member 24 is inserted into the hole 42. The shape of the hole 42 is a rectangular shape as similar to that of the longitudinal section of the connector member 24. This hole 42 has a shape substantially similar to that of the longitudinal section of the connector member 24, and is formed slightly larger than the connector member 24. The inner surface 42A of the hole 42 is an example of a holder to temporarily hold the connector member 24 as described later.

The above description is about one electronic apparatus 10 among the multiple electronic apparatuses 10 illustrated in FIG. 1A, but the other electronic apparatus 10 among the multiple electronic apparatuses 10 illustrated in FIG. 1A is same as the one electronic apparatus 10 as described above. The electronic devices 14 in the one electronic apparatus 10 and the electronic devices 14 in the other electronic apparatus 10 are connected with cables 22 as described later.

The above-described electronic device 14, rack 12, and jig 40 constitute the electronic apparatus 10, and the rack 12 and the jig 40 form a rack device 20 in this electronic apparatus 10. The electronic apparatus 10 may be on the market together with the electronic device 14, the rack 12, and the jig 40 or may be on the market together with the electronic device 14 and the jig 40 without the rack 12. Also, the electronic apparatus 10 may be on the market, as the rack device 20 including the rack 12 and the jig 40 without the electronic device 14 or the jig 40 may be on the market separately from the electronic device 14 and the rack 12 as a stand-alone unit.

Next, a cable connection method for an electronic device according to the first embodiment is described.

First, as illustrated in FIG. 1B, the multiple racks 12 are carried in an installation room 26 such as a computer room. Then, the multiple racks 12 are arranged in multiple arrangement spaces 28 different from each other in the installation room 26.

Also, the jig 40 is placed in the rack 12 while being housed inside the slit 18 (see, FIG. 3) which is opened to the back surface of the rack 12. In the first embodiment, the rack 12 where to place the jig 40 is an example of an arrangement location of the electronic device 14. The work of carrying the rack 12 into the arrangement space 28 and the work of installing the jig 40 into the rack 12 may be performed in any order or may be performed simultaneously.

After that, before the multiple electronic devices 14 are mounted on the racks 12, the cables 22 are routed between the multiple racks 12 (between the jig 40 placed in one rack 12 and the jig 40 placed in another rack 12) as illustrated in FIG. 1B.

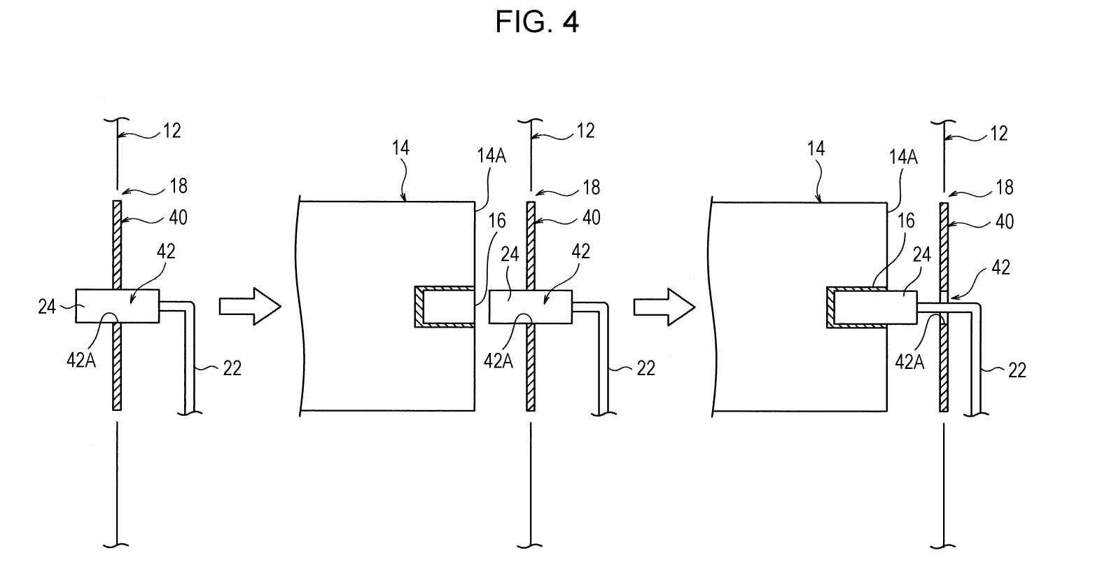

In other words, an intermediate portion 22A of the cable 22 is routed under the floor of the installation room 26, and both end portions 22B of the cable 22 are routed from the floor to the jig 40 along a support, or a frame or the like of the rack 12, for example. Also, as illustrated on a left drawing of FIG. 4, the connector member 24 connected with each of both ends of the cable 22 is inserted into the hole 42 formed in the jig 40. The connector member 24 inserted into the hole 42 is caught by the inner surface 42A of the hole 42 and held by the inner surface 42A of the hole 42. In order to easily catch the connector member 24, the inner surface 42A of the hole 42 may be formed to have an uneven portion or may be additionally provided with a member with high friction coefficient such as a rubber. Then, a routing check of the cable 22 to check whether the connector members 24 are arranged in correct locations or not is performed. Before or after the routing check of the cable 22, a forming work of holding the cables 22 in a predetermined shape by fixing the cables 22 to the support or frame of the rack 12 using a fixture may be performed.

Next, after the work of routing the cables 22 between the multiple racks 12, which is illustrated in FIG. 1B, is completed as described above, each electronic device 14 is mounted (arranged) in the rack 12 as illustrated in a center drawing of FIG. 4. In this process, if the electronic device 14 is mounted in a correct location of the rack 12, the back surface 14A of the electronic device 14 is opposed to the jig 40 and each hole 42 is aligned with the placement location of the corresponding connector attachment member 16. In addition, if the back surface 14A is opposed to the jig 40 as described above, each connector attachment member 16 provided on the back surface 14A is opposed to the connector member 24 inserted into the hole 42 corresponding to this connector attachment member 16.

Then, as illustrated in a right drawing of FIG. 4, each connector member 24 is brought close to the connector attachment member 16 through the corresponding hole 42, and the connector member 24 is connected with the connector attachment member 16. As described above, as illustrated in FIG. 1A, the electronic devices 14 mounted on the multiple racks 12 are connected with each other by the cables 22 to constitute the electronic system S1.

Hereinafter, advantageous effects of the first embodiment are described.

As described above, in the first embodiment, before multiple electronic devices 14 are mounted on each rack 12, multiple connector members 24 may be held by jigs 40 placed in the rack 12. Accordingly, as illustrated in FIG. 1B, before the multiple electronic devices 14 are mounted on each rack 12, the work of routing cables 22 between the multiple racks 12 may be completed. Moreover, as the work of routing the cables 22, a work of routing an intermediate portion 22A of the cable 22 under the floor of an installation room 26, a work of routing both end portions 22B of the cables 22 from under the floor to each jig 40, and the checking of the routing of the cables 22 may be continuously performed. Also, if desired, the work of forming of the cables 22 may be performed as a part of the work of routing the cables 22.

Accordingly, as compared with the case where a rack 12 is arranged in an arrangement space 28 and an intermediate portion 22A of a cable 22 is routed under the floor of an installation room 26, and then electronic devices 14 are mounted on the rack 12, and thereafter other remaining works are performed, the interruption in the work of routing the cables 22 may be avoided. As a result, the working efficiency in routing the cables 22 (in cable connection work) may be improved, and, thus the working efficiency for building an electronic system S1 may be improved.

Also, in the first embodiment, the work of routing the cables 22 may be performed before multiple electronic devices 14 are mounted on each rack 12 as described above. Accordingly, the electronic devices 14 may not act as an obstacle in the work of routing the cables 22 or the work of forming the cables 22. Thus, the work efficiency in routing the cables 22 may be further improved.

Also, in the first embodiment, the multiple connector members 24 (all the connector members 24 to be connected with one electronic device 14) may be held by one jig 40. This also may improve the work efficiency in routing the cables 22.

Also, the jig 40 has a simple configuration with the multiple holes 42 into which the multiple connector members 24 are inserted. Accordingly, the cost of manufacturing the jig 40 may be reduced. Thus, even when the jig 40 is used, an increase in the cost may be reduced.

Hereinafter, a modification of the first embodiment is described.

In the above-described first embodiment, the multiple holes 42 are formed in the jig 40 and the inner surface 42A of each hole 42 is used as an example of the holder to hold the connector member 24. However, a holder formed by a structure other than the holes may be provided in the jig 40. Also, the number of the holders in the jig 40 may be any number of one or larger, or the number of jigs 40 provided in one electronic device 14 may be any number of one or larger.

Also, in the above-described first embodiment, the connector member 24 is held by the inner surface 42A of the hole 42. However, for example, an end of the cable 22 on the connector member 24 side may be held by the inner surface 42A of the hole 42, or both the connector member 24 and an end of the cable 22 on the connector member 24 side may be held by inner surface 42A of the hole 42.

Also, the jig 40 is more preferably formed in a plate shape but may be formed in a shape other than the plate shape.

### Second Embodiment

Hereinafter, a second embodiment is described.

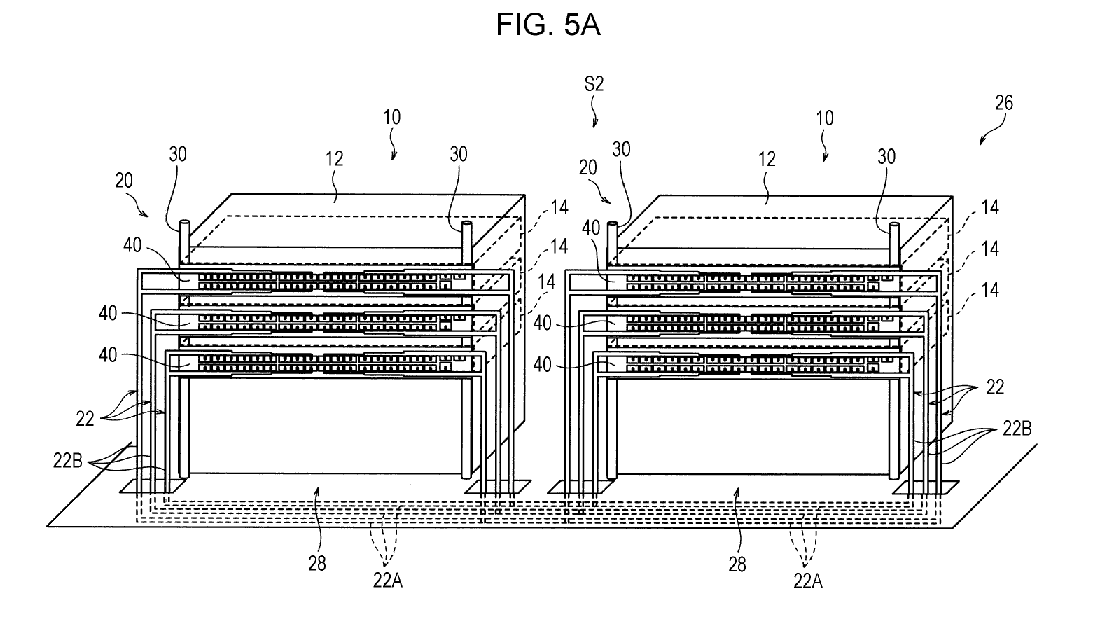

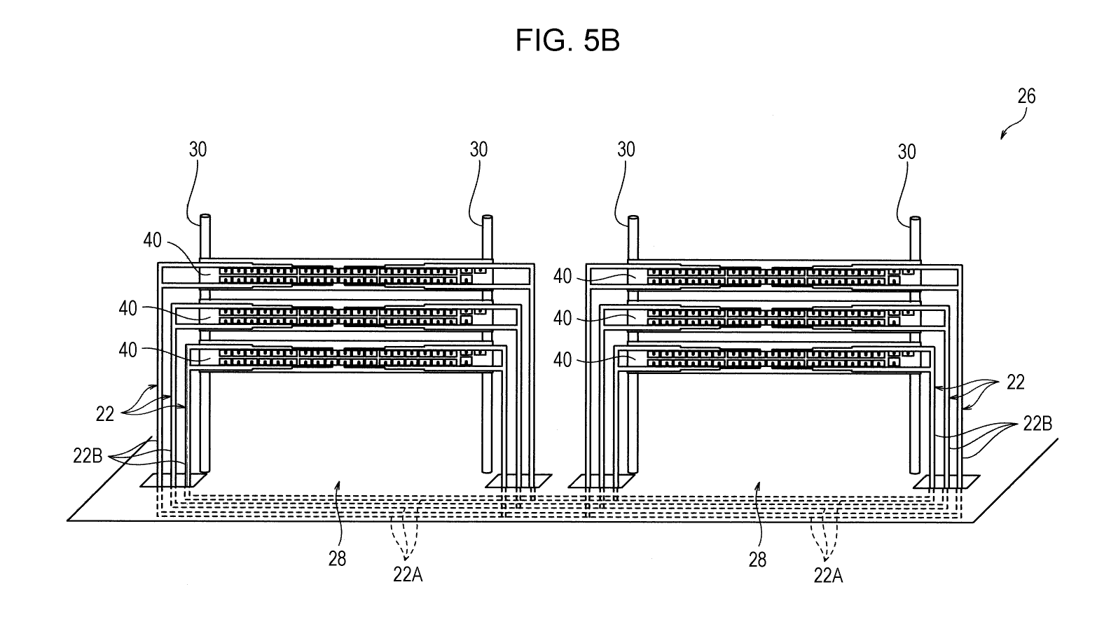

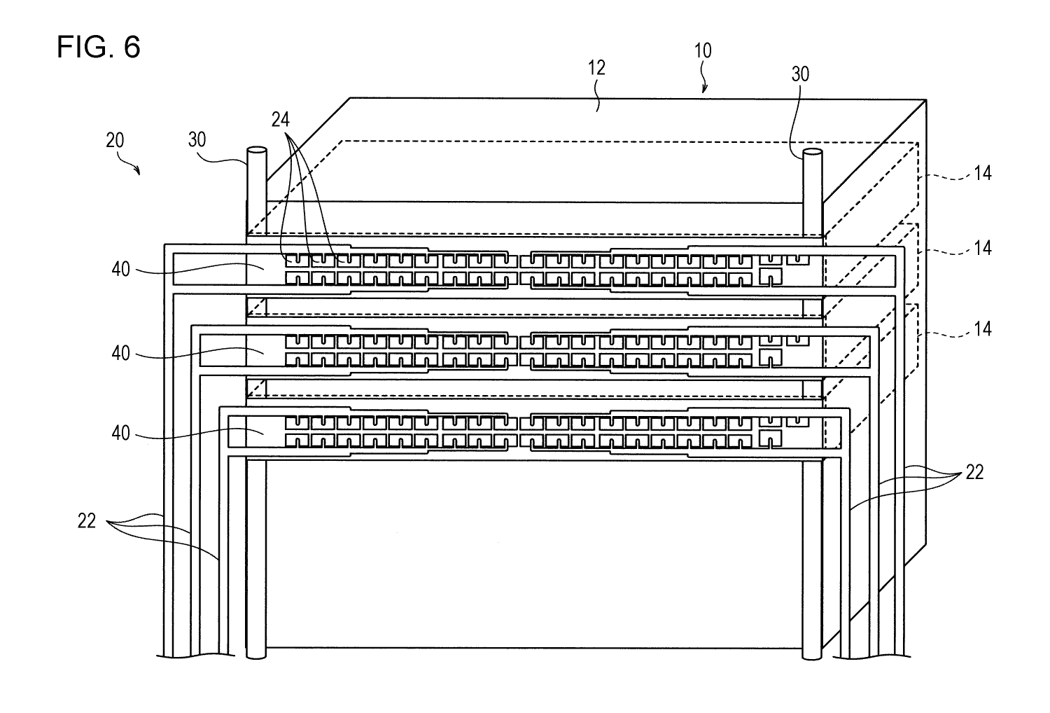

In an electronic system S2 according to a second embodiment, illustrated in FIG. 5A, a cable connection method is different from that described in the first embodiment in the following points.

More specifically, first of all, as illustrated in FIG. 5B, a pair of supports 30 are provided in each of multiple arrangement spaces 28 in an installation room 26. Each arrangement space 28 is an example of an arrangement location where to arrange an electronic device 14, and the supports 30 is an example of a supporting member.

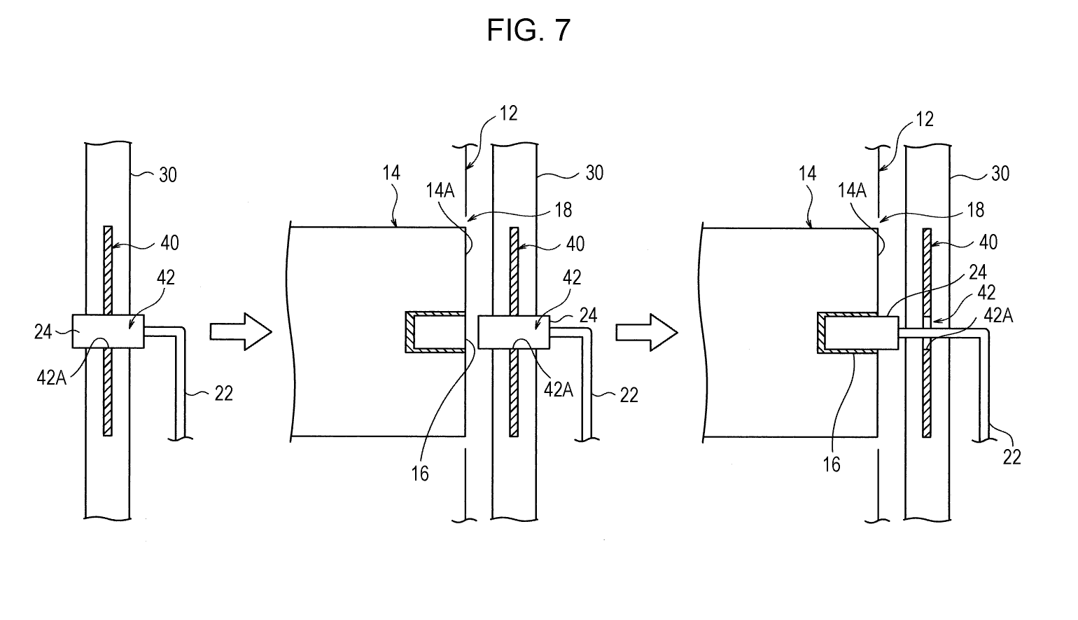

Also, multiple jigs 40 are assembled with the pair of supports 30. The multiple jigs 40 are supported by the pair of supports 30, so that they are respectively placed in predetermined heights from the floor of the installation room 26. It is assumed in this case that the placement height of each jig 40 is a height corresponding to a back surface 14A (see FIG. 7) of the electronic device 14 in a state of being mounted on a rack 12 to be described later.

Subsequently, before the multiple racks 12 are carried in the installation room 26, the cables 22 are routed between the multiple arrangement spaces 28 (between the jig 40 placed in the one arrangement space 28 and the jig 40 placed in the other arrangement space 28) as illustrated in FIG. 5B.

In other words, an intermediate portion 22A of the cable 22 is routed under the floor of the installation room 26, and portions on both end sides 22B of the cable 22 are routed from under the floor to the jig 40 along the support 30 or the like, for example. Also, as illustrated on the left of FIG. 7, the connector member 24 connected with each of both ends of the cable 22 is inserted into the hole 42 formed in the jig 40. The connector member 24 inserted into the hole 42 is caught by the inner surface 42A of the hole 42 and held by the inner surface 42A of the hole 42. Furthermore, a routing check for the cables 22 to check whether or not the connector members 24 are arranged in correct locations is performed. In addition, before or after checking the routing of the cables 22, the work of forming the cables 22 by holding the cables 22 in a predetermined shape may be performed.

Next, after the work of routing the cables 22 between the multiple arrangement spaces 28, which is illustrated in FIG. 5B, is completed as described above, as illustrated in FIG. 5A, the racks 12 are carried in the installation room 26 in a state where the multiple electronic devices 14 are mounted on the racks 12. Then, the racks 12 are installed in the arrangement spaces 28. In this process, as illustrated in the center drawing of the FIG. 7, if the rack 12 is arranged in a correct location of the arrangement space 28, the back surface 14A of the electronic device 14 mounted on the rack 12 is opposed to the jig 40 and each hole 42 is aligned with the arrangement location of the corresponding connector attachment member 16. Also, if the back surface 14A is opposed to the jig 40, each connector attachment member 16 provided on the back surface 14A is opposed to the connector member 24 inserted into the hole 42 corresponding to this connector attachment member 16.

Then, as illustrated on the right of FIG. 7, each connector member 24 is brought close to the connector attachment member 16 through each hole 42, and the connector member 24 is connected with the connector attachment member 16. As described above, as illustrated in FIG. 5A, the electronic devices 14 mounted on the multiple racks 12 are connected with each other by the cables 22 to constitute the electronic system S2.

Hereinafter, advantageous effects of the second embodiment are described.

As described above, in the second embodiment, before each rack 12 on which the multiple electronic devices 14 are mounted is arranged in the arrangement space 28, the multiple connector members 24 may be held by the jig 40 placed in each arrangement space 28. Accordingly, as illustrated in FIG. 5B, before the multiple racks 12 are carried in the arrangement space 28, the work of routing the cables 22 between the multiple arrangement spaces 28 may be completed. Moreover, as the work of routing the cables 22, the work of routing an intermediate portions 22A of the cables 22 under the floor of an installation room 26, the work of routing both end portions 22B of the cables 22 from under the floor to each jig 40, and checking of the routing of the cables 22 may be continuously performed. Also, if desired, the work of forming the cables 22 may be performed as a part of the work of routing the cables 22.

Accordingly, as compared with the case where the intermediate portion 22A of the cable 22 is routed under the floor of the installation room 26, and then the racks 12 on which the electronic devices 14 are mounted are arranged in the arrangement space 28, and thereafter other remaining works are performed, the interruption in the work of routing the cables 22 may be avoided. As a result, the working efficiency in routing the cables 22 (in cable connection work) may be improved, and, thus, the working efficiency in building the electronic system S2 may be improved.

Also, in the second embodiment, as described above, before the racks 12 on which the multiple electronic devices 14 are mounted are arranged in the arrangement space 28, the work of routing the cables 22 may be performed. Accordingly, the racks 12 and the electronic devices 14 may not act as an obstacle in the work of routing the cables 22 or the work of forming the cables 22. Thus, the work efficiency in routing the cables 22 may be further improved.

Also, in the second embodiment, the multiple connector members 24 (all the connector members 24 to be connected with one electronic device 14) may be held by one jig 40. This also may improve the work efficiency in routing the cables 22.

Hereinafter, a modification of the second embodiment is described.

In the above-described second embodiment, the electronic apparatus 10 includes the racks 12, but the electronic apparatus 10 does not have to include the racks 12. Also, when the electronic apparatus 10 does not include the racks 12, the electronic devices 14 may be directly arranged in the arrangement space 28 without being mounted on the rack 12.

Also, in the second embodiment, the jig 40 may include a modification similar to that of the first embodiment.

Also, in the above second embodiment, the jig 40 is supported by the supports 30 as an example of the supporting members. However, the jig 40 may be supported by a supporting member other than the supports 30. Also, the supports 30 or the supporting members may be removed after the work of routing the cables 22 is completed.

### Third Embodiment

Hereinafter, a third embodiment is described.

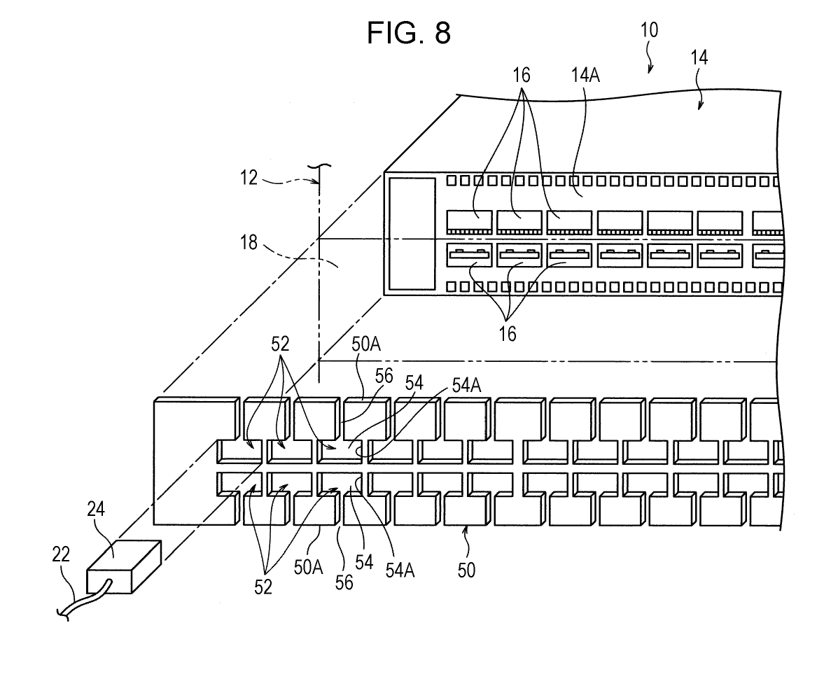

A third embodiment is different from the above-described first embodiment in that a jig has a different configuration. In other words, as illustrated in FIG. 8, a jig 50 according to the third embodiment has multiple cutouts 52 passing through the jig 50 in the thickness direction in place of multiple holes 42 (see, FIG. 3) formed in the jig 40 in the first embodiment. Each of the multiple cutouts 52 is an example of an opening. Each cutout 52 has a substantially T-letter shape in the front view of the jig 50, and includes an insertion port 54 to which a connector member 24 is inserted and an open mouth 56 for a cable 22 to pass.

The insertion ports 54 are formed corresponding to multiple connector attachment members 16 so as to be aligned with respective arrangement locations of the multiple connector attachment members 16 in a state where the jig 50 is placed in a rack 12. The shape of the insertion port 54 is a rectangular shape as substantially similar to that of the longitudinal section of the connector member 24 inserted into the insertion port 54. The shape of the insertion port 54 has a similar shape with the longitudinal section of the connector member 24 and is formed slightly larger than the connector member 24. As described later, an inner surface 54A of the insertion port 54 is an example of a holder to temporarily hold the connector member 24.

The open mouth 56 has a width large enough to allow the cable 22 to pass therethrough and is formed to be wider than the insertion port 54. The open mouth 56 is positioned in the center portion of the insertion port 54 in the breadth direction and extends in the longitudinal direction of the jig 50. One end of the open mouth 56 is connected with the insertion port 54 and the other end of the open mouth 56 opens in an edge 50A on the longitudinal end side of the jig 50.

Then, in the third embodiment, as similar to the first embodiment, the work of carrying the rack 12 in, the work of routing the cables 22, the work of mounting the electronic devices 14 on the rack 12, and the work of connecting the connector members 24 and the connector attachment members 16 are performed.

In the work of routing the cables 22, each connector member 24 is inserted into the insertion port 54 formed in the jig 50. The connector member 24 inserted into the insertion port 54 is caught by the inner surface 54A of the insertion port 54 and is held by the inner surface 54A of the insertion port 54.

Also, if the electronic devices 14 are mounted in the correct locations of the rack 12 in the work of mounting the electronic devices 14 on the rack 12, the back surface 14A of the electronic device 14 is opposed to the jig 50 and multiple insertion ports 54 are aligned with the respective arrangement locations of the multiple connector attachment members 16. Moreover, if the back surface 14A is opposed to the jig 50 as described above, each of the multiple connector attachment members 16 which are provided in back surface 14A is opposed to the corresponding one of the connector members 24 respectively inserted in the insertion ports 54. Then, the connector members 24 are brought close to the connector attachment members 16 through the insertion ports 54, and the connector members 24 are respectively connected with the connector attachment members 16.

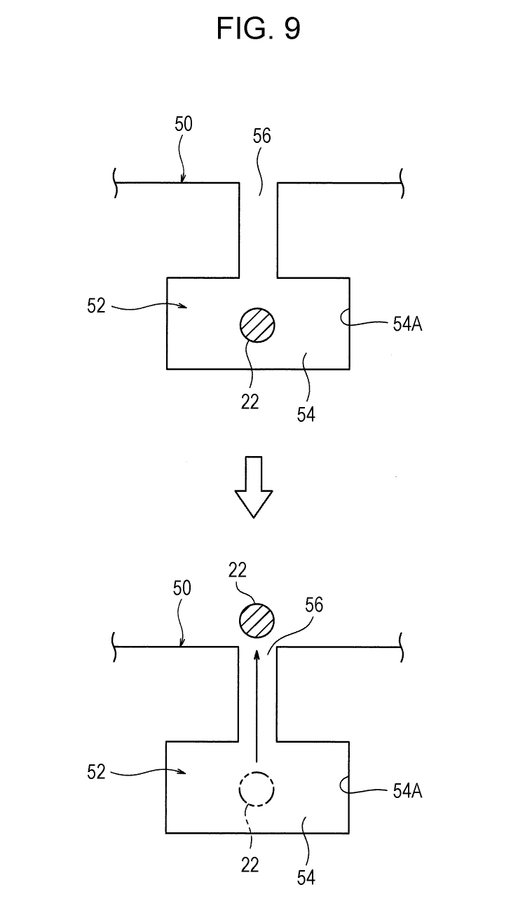

Then, after the work of connecting the connector members 24 and the connector attachment members 16 is completed, as illustrated in FIG. 9, the cable 22 in the state of being inserted into the insertion port 54 passes through the open mouth 56 and comes out from the cutout 52, and then the cable 22 is taken out from the jig 50. Also, when all the cables 22 are taken out from the jig 50, the jig 50 can be taken out from the rack 12 as illustrated in FIG. 8. Then, the jig 50 is removed from the rack 12 and a series of the works are terminated.

As described above, in the third embodiment, after the work of connecting the connector members 24 and the connector attachment members 16 is completed, the jig 50 may be removed from the rack 12. Accordingly, the jig 50 is reusable for another cable connection work. This may reduce the cost of the reusable jig 50 as compared with the case where the jig 50 remains being placed in the rack 12.

The above description is the case where the jig 50 according to the third embodiment is applied to the work of connecting the cables 22 according to the first embodiment, but the jig 50 according to the third embodiment may be also applied to the work of connecting the cables 22 according to the second embodiment. In other words, the jig 50 may be removed from the arrangement space 28 after the work of installing the jig 50 to the arrangement space 28 in FIG. 5A, the work of routing the cables 22, the work of carrying the rack 12 on which the electronic devices 14 are mounted, and the work of connecting the connector members 24 and the connector attachment members 16.

For example, in the third embodiment, as similar to the first and second embodiments, other than a connector member 24, an end of the cable 22 on a connector member 24 side may be held by the inner surface 54A of the insertion port 54. Also, both the connector member 24 and an end of the cable 22 on the connector member 24 side may be held by the inner surface 54A of the insertion port 54.

Also, the jig 50 may be formed so that the open mouth 56 has a width large enough to allow the connector member 24 to pass therethrough. Then, the jig 50 may be removed from the rack 12 by causing the connector member 24 to pass through the open mouth 56 or causing both the connector member 24 and the cable 22 to pass.

Also, in the third embodiment, the modifications in the first and second embodiments may be appropriately applied.

### Fourth Embodiment

Hereinafter, a fourth embodiment is described.

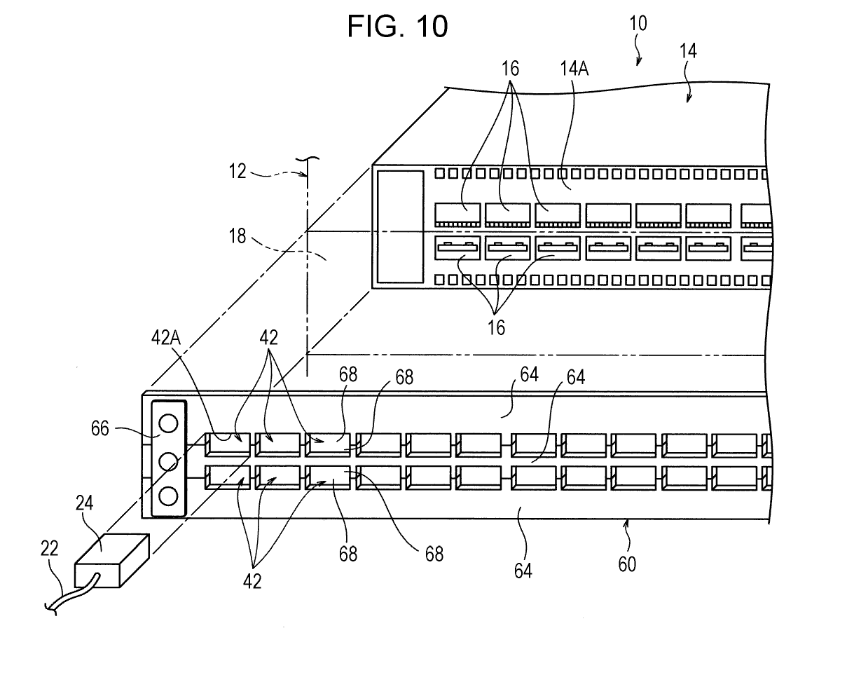

A fourth embodiment is different from the first embodiment in that a jig has a different configuration. In other words, as illustrated in FIG. 10, a jig 60 in the fourth embodiment has multiple divided members 64 which are divided in the longitudinal direction of the jig 60. The multiple divided members 64 are fixed with each other by a fastener 66. The jig 60 has the similar structure with the jig 40 (see, FIG. 3) in the first embodiment in the state where the multiple divided members 64 are fixed with each other by the fastener 66, and has multiple holes 42. The multiple holes 42 are formed by combining rectangular cutouts 68 respectively formed in the multiple divided members 64.

Then, in the fourth embodiment, as similar to the first embodiment, a work of carrying racks 12 in, a work of routing cables 22, a work of mounting electronic devices 14 on the racks 12, and a work of connecting connector members 24 and connector attachment members 16 are performed.

The connector member 24 is inserted into the hole 42 formed in the jig 60 in the work of routing cables 22. The connector member 24 inserted into the hole 42 is caught by the inner surface 42A of the hole 42 (the inner surface of the cutout 68) and held by the inner surface 42A of the hole 42.

Also, if the electronic devices 14 are mounted in the correct locations of the rack 12 in the work of mounting the electronic devices 14 on the rack 12, the back surface 14A of the electronic device 14 is opposed to the jig 60 and multiple holes 42 are aligned with the respective arrangement locations of the multiple connector attachment members 16. Moreover, if the back surface 14A is opposed to the jig 60 as described above, each of the multiple connector attachment members 16 which are provided in back surface 14A is opposed to the corresponding one of the connector members 24 respectively inserted into the holes 42. Then, the connector members 24 are brought close to the connector attachment members 16 through the corresponding holes 42, and the connector members 24 are respectively connected with the connector attachment members 16.

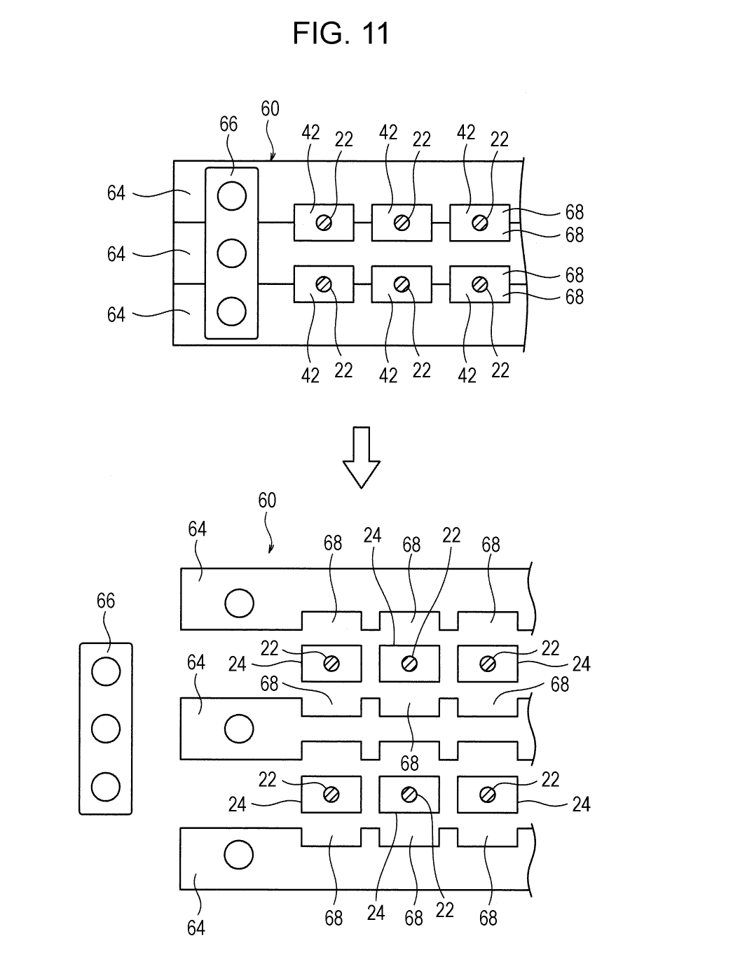

Subsequently, after the work of connecting the connector members 24 and the connector attachment members 16 is completed, as illustrated in FIG. 11, the fastener 66 is detached from the multiple divided members 64 and multiple divided members 64 are divided, the jig 60 (multiple divided members 64) are removed from the cables 22. Then, the jig 60 is removed from the rack 12 and a series of the works are completed.

As described above, in the fourth embodiment, after the work of connecting the connector members 24 and the connector attachment members 16, which are illustrated in FIG. 10, is completed, the jig 60 (the multiple divided members 64) may be removed from the rack 12. Accordingly, the jig 60 is reusable for another cable connection work. This may reduce the cost of the reusable jig 60 from the total cost as compared with the case where the jig 60 remains being placed in the rack 12.

The above description is the case where the jig 60 according to the fourth embodiment is applied to the work of connecting the cables 22 according to the first embodiment, but the jig 60 according to the fourth embodiment may be applied to the work of connecting the cables 22 according to the second embodiment. In other words, the jig 60 may be removed from the arrangement space 28 after the work of placing the jig 60 to the arrangement space 28 in FIG. 5A, the work of routing cables 22, the work of carrying the rack in 12 on which the electronic devices 14 are mounted, and the work of connecting the connector members 24 and the connector attachment members 16.

Also, in the fourth embodiment, the modifications in the first and second embodiments may be appropriately applied.

### Fifth Embodiment

Hereinafter, a fifth embodiment is described.

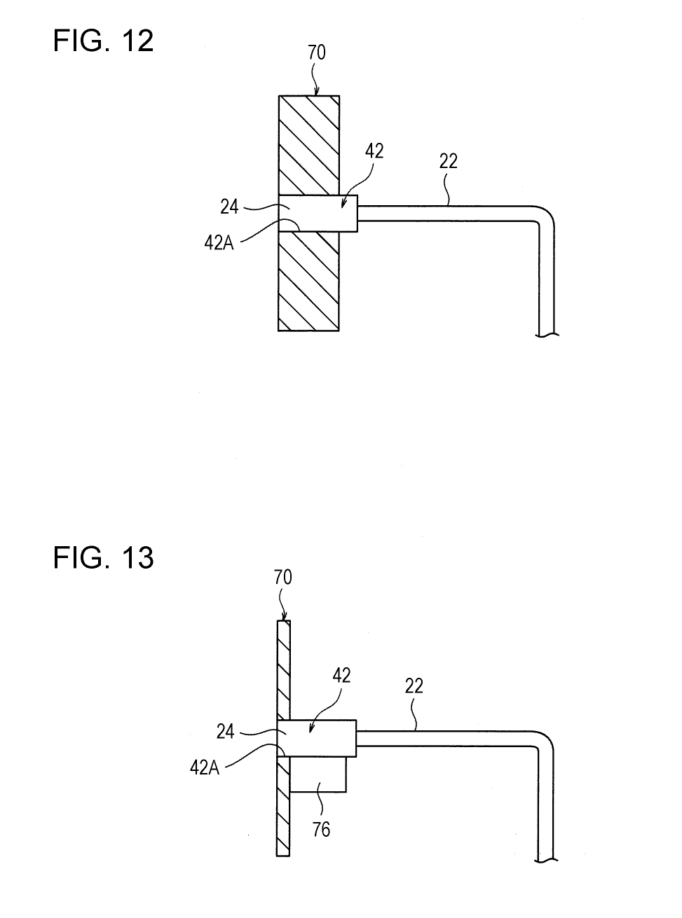

A fifth embodiment is different from the first embodiment in that a jig has a different configuration. In other words, as illustrated in FIG. 12, a jig 70 in the fifth embodiment is formed in a thick plate shape having a length direction of a connector member 24 as the thickness direction. As similar to the jig 40 (see FIG. 3) in the first embodiment, the jig 70 has multiple holes 42 passing through the jig 70 in its thickness direction. The thickness of the jig 70 is ensured in such an extent that a connector member 24 can be held by an inner surface 42A of the hole 42 over the length direction of the connector member 24.

The thickness of the jig 70 in the length direction of the connector member 24 is a thickness of the jig 70 that has the same length as the total length of the connector member 24 in the length direction, a thickness that exceeds the total length of the connector member 24 in the length direction, or a thickness that is slightly shorter than the total length of the connector member 24 in the length direction. In the fifth embodiment illustrated in FIG. 12, as one example, the thickness of the jig 70 is slightly shorter than the total length of the connector member 24 in the length direction.

Then, in the fifth embodiment, when the connector member 24 is inserted into the hole 42 formed in the jig 70 in the work of routing cables 22, the connector member 24 is supported by an inner surface 42A (lower surface in the vertical direction) of the hole 42 over the length direction of the connector member 24 from the lower side in the vertical direction. Accordingly, since the jig 70 is formed to be thick, the connector member 24 may be more stably held (held in a horizontal state) by the inner surface 42A of the hole 42. Accordingly, the connector member 24 may be kept away from being dropped from the jig 70, and thus the work efficiency of the work of routing the cables 22 may be improved.

As illustrated in FIG. 13, in the fifth embodiment, the jig 70 may be configured of a thin plate as similar to the jig 40 (see, FIG. 3) in the first embodiment, and a supporting portion 76 may be formed in an edge of the hole 42 in the jig 70. The supporting portion 76 is formed by extending the inner surface 42A (surface on the lower side in the vertical direction) of the hole 42. Then, the connector member 24 may be supported by the supporting portion 76 from the lower side in the vertical direction over the length direction. Even when it is configured as described above, the supporting portion 76 may stably hold (hold in the horizontal state) the connector member 24. Thus, the connector member 24 may be kept away from being dropped from the jig 70.

The length in which the supporting portion 76 and the inner surface 42A of the hole 42 are added may be any one of cases where the length is equal to the total length of the connector member 24 in the length direction, where the length exceeds the total length of the connector member 24 in the length direction, and where the length is slightly shorter than the total length of the connector member 24 in the length direction. In the example illustrated in FIG. 13, as one example, the length in which the supporting portion 76 and the inner surface 42A of the hole 42 are added is slightly shorter than the total length of the connector member 24 in the length direction.

Also, the structure of the jig 70 in the fifth embodiment, in other words, the structure in which the inner surface 42A of the hole 42 and the supporting portion 76 support the connector member 24 from the lower side in the vertical direction over the length direction of the connector member 24 may be applied to the second to fourth embodiments in addition to the first embodiment.

Also, in the fifth embodiment, the modifications in the first to fourth embodiments may be appropriately applied.

### Sixth Embodiment

Hereinafter, a sixth embodiment is described.

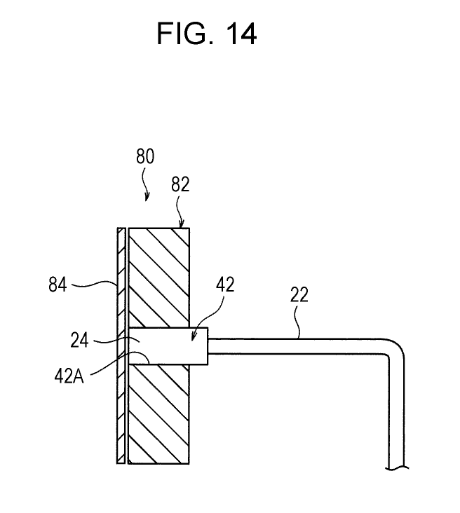

A sixth embodiment is different from the fifth embodiment in that a jig has a different configuration. In other words, as illustrated in FIG. 14, a jig 80 in the sixth embodiment has a plate-like jig body 82 and a cover 84 attachable/detachable to the jig body 82. The jig body 82 has a structure similar to that of the jig 70 (see FIG. 12) in the thick plate shape in the fifth embodiment. In other words, the jig 80 in the sixth embodiment is one in which the cover 84 is added to the jig 70 in the fifth embodiment. The cover 84 has a shape and size which entirely cover the jig body 82 including tip end surfaces of multiple connector members 24.

Then, in the sixth embodiment, the cover 84 is attached in the jig body 82 in a work of routing cables 22 before the connector members 24 are connected with connector attachment members. Also, this common cover 84 covers the entire surface of the jig body 82 including the tip end surfaces of the multiple connector members 24. Thus, the tip end portions of the multiple connector members 24 may be kept away from dust to be attached.

Also, in the sixth embodiment, the tip end surfaces of the multiple connector members 24 may be covered all together by the common cover 84. Accordingly, the work efficiency in connecting the connector members 24 with the connector attachment members may be improved as compared with the case where a cap covers each of the tip end portions of the connector members 24.

The cover 84 in the sixth embodiment may be applied to the first to fourth embodiment in addition to the fifth embodiment.

Also, in the sixth embodiment, the modifications according to the first to fifth embodiments may be appropriately applied.

### Seventh Embodiment

Hereinafter, a seventh embodiment is described.

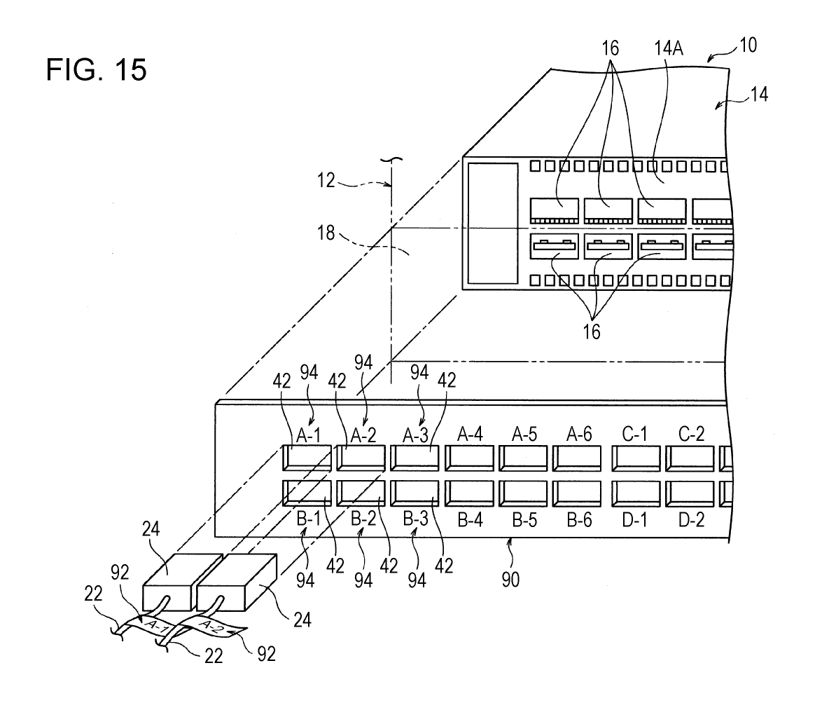

As illustrated in FIG. 15, a seventh embodiment is different from the first embodiment in that display portions 92, 94 as examples of an identifier information portion and an identifiable information portion are added to a cable 22 and a jig 90. The display portions 92, 94 include at least one of characters, numbers, and signs. The display portion 94 added to the jig 90 is displayed dedicated to (adjacent to) each of holes 42. The display portions 92 respectively provided in the cables 22 contain information different from one another, and the display portions 94 provided in the jig 90 correspond to (for example, contains the same identification with) the display portions 92 respectively provided in the cables 22.

In the seventh embodiment, a matching work of matching the display portions 92 provided in the cables 22 with the display portions 94 provided to the holes 42 is performed to check the routing of the cables 22. Accordingly, the work efficiency in the checking of routing of the cable 22 may be improved.

In the seventh embodiment, the display portion 92 may be provided in the connector member 24 or may be provided in both the connector member 24 and the cable 22.

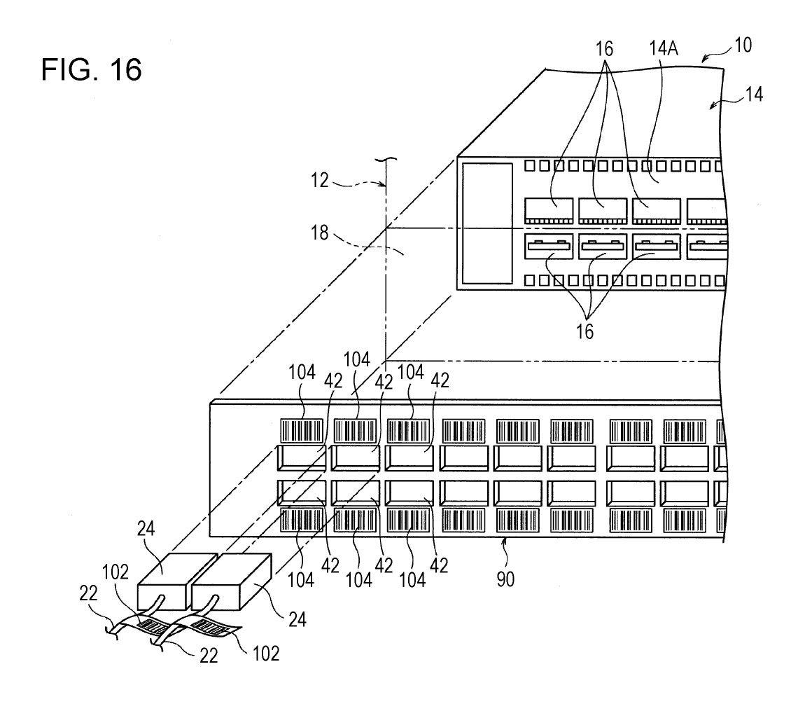

Also, in the seventh embodiment, in place of the display portions 92, 94, as illustrated in FIG. 16, barcodes 102, 104 as examples of an identifier information portion and an identifiable information portion may be added to the cable 22 and jig 90. The barcodes 102 respectively provided in the cables 22 are different from one another, and the barcodes 104 provided in the jig 90 corresponding to the holes 42 correspond to (for example, the content is same with) the barcodes 102 respectively provided in the cables 22.

Even in the case where these barcodes 102, 104 are used, for example, a barcode reader or the like is used to perform a work of matching the barcodes 102 provided in the cables 22 with the barcodes 104 for the holes 42. Accordingly, the checking of the routing of the cable 22 may be performed.

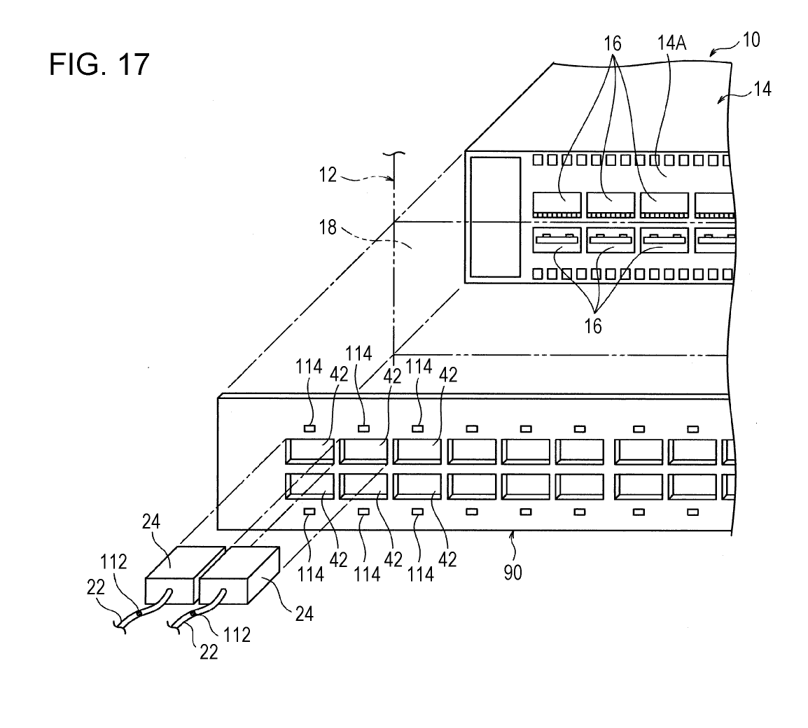

Also, in the seventh embodiment, in place of the display portions 92, 94 and the barcodes 102, 104, as illustrated in FIG. 17, information storage elements 112, 114 as examples of an identifier information portion and an identifiable information portion may be added to the cable 22 and the jig 90. As one example, the information storage elements 112, 114 use an integrated circuit (IC) tag chip. Pieces of information stored in the information storage elements 112 respectively provided in the cables 22 are different from one another and the information storage elements 114 provided in the jig 90 corresponding to the holes 42 correspond to (for example, the content is same with) the stored information of the information storage element 112 provided in each cable 22.

Even when these information storage elements 112, 114 are used, for example, a work of matching the information storage elements 112 provided in the cables 22 with the information storage elements 114 for to the holes 42 may be performed by using a reading device or the like. Accordingly, the checking of the routing of the cables 22 may be performed.

Besides the display portions 92, 94, the barcodes 102, 104, and the information storage elements 112, 114, the seventh embodiment may use an identifier information portion and an identifiable information portion which have functions same or similar to those described above.

Also, the identifier information portion and identifiable information portion such as the display portions 92, 94, the barcodes 102, 104, and the information storage elements 112, 114 in the seventh embodiment may be applied to the second to sixth embodiments in addition to the first embodiment.

Also, in the seventh embodiment, the modifications according to the first to sixth embodiment may be appropriately applied.

As described above, multiple embodiments are disclosed. However, it is natural that the embodiments discussed herein are not limited to the above-described embodiments and various changes may be made hereto without departing from the spirit and scope thereof.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A cable connection method for an electronic device, comprising:
placing a jig in an arrangement location in which the electronic device is to be arranged, and holding by a holder at least one of a cable and a connector member connected with the cable, the holder provided in a location in the jig corresponding to a connector attachment member in the electronic device;
arranging the electronic device in the arrangement location; and
connecting the connector member with the connector attachment member.

2. The cable connection method for an electronic device according to claim 1, comprising:
placing the jig in each of a plurality of the arrangement locations; and
routing the cable between the plurality of arrangement locations before a plurality of the electronic devices are arranged in their respective different arrangement locations.

3. The cable connection method for an electronic device according to claim 1, comprising:
placing the jig in a rack as the arrangement location; and
mounting the electronic device on the rack.

4. The cable connection method for an electronic device according to claim 1, comprising:
placing the jig in an arrangement space as the arrangement location; and
arranging the rack in the arrangement space in a state where the electronic device is mounted on the rack.

5. The cable connection method for an electronic device according to claim 1, comprising holding at least one of the cable and the connector member by each of a plurality of the holders provided in the jig, the holders respectively corresponding to a plurality of the connector attachment members in the electronic device.

6. The cable connection method for an electronic device according to claim 1, comprising:
inserting at least one of the cable and the connector member into an opening formed in the jig; and
holding the at least one of the cable and the connector member by an inner surface of the opening as the holder.

7. The cable connection method for an electronic device according to claim 6, comprising:
inserting at least one of the cable and the connector member into a cutout as the opening formed in the jig, and holding the at least one of the cable and the connector member by an inner surface of the cutout; and
connecting the connector member with the connector attachment member and thereafter removing the jig from the arrangement location by causing the at least one of the cable and the connector member to pass through an open mouth of the cutout.

8. The cable connection method for an electronic device according to claim 6, wherein
the jig includes a plurality of divided members in each of which a cutout forming a hole as the opening is formed, and
the cable connection method for an electronic device comprises:
inserting at least one of the cable and the connector member into the hole and holding the at least one of the cable and the connector member by an inner surface of the hole; and
connecting the connector member with the connector attachment member, and thereafter removing the jig from the arrangement location by dividing the jig into the multiple divided members.

9. The cable connection method for an electronic device according to claim 6, wherein
the jig is a jig whose thickness direction is set to be a length direction of the connector member, and
the cable connection method for an electronic device comprises:
inserting the connector member into the opening passing through the jig in the thickness direction, and supporting the connector member by the inner surface of the opening over the length direction of the connector member.

10. The cable connection method for an electronic device according to claim 6, comprising:
inserting the connector member into the opening, and supporting the connector member over the length direction of the connector member by a supporting portion formed in an edge portion of the opening.

11. The cable connection method for an electronic device according to claim 1, comprising:
holding at least one of the cable and the connector member by the holder, and covering a tip end portion of the connector member with a cover.

12. The cable connection method for an electronic device according to claim 1, wherein the jig includes an identifiable information portion dedicated to the holder, the identifiable information portion corresponding to an identifier information portion provided in at least one of the cable and the connector member.

13. A jig to be opposed to a cable connection surface of an electronic device, the jig comprising:
a holder which is provided in a location corresponding to a connector attachment member provided in the cable connection surface, and is configured to hold at least one of a connector member to be connected with the connector attachment member, and a cable connected with the connector member.

14. An electronic apparatus, comprising:
an electronic device including a cable connection surface in which a connector attachment member is provided; and
a jig including a holder which is provided to be opposed to the cable connection surface, is provided in a location corresponding to the connector attachment member, and is configured to hold at least one of a connector member to be connected with the connector attachment member and a cable connected with the connector member.

15. A rack device, comprising:
a rack on which an electronic device is to be mounted; and
a jig including a holder which is provided to be opposed to a cable connection surface in the electronic device, is provided in a location in the cable connection surface corresponding to a connector attachment member, and is configured to hold at least one of a connector member to be connected with the connector attachment member and a cable connected with the connector member.
